(19) United States
(12) Patent Application Publication
(10) Pub. No.: US 2014/0315016 A1
(43) Pub. Date: Oct. 23, 2014

(54) ADHESIVE SUBSTANCE, IN PARTICULAR FOR ENCAPSULATING AN ELECTRONIC ASSEMBLY

(71) Applicant: tesa SE, Hamburg (DE)

(72) Inventors: Thilo Dollase, Hamburg (DE); Thorsten Krawinkel, Hamburg (DE); Minyoung Bai, Hamburg (DE)

(21) Appl. No.: 14/351,800

(22) PCT Filed: Oct. 19, 2012
(86) PCT No.: PCT/EP2012/070779

§ 371 Date: Apr. 14, 2014

(30) Foreign Application Priority Data
Oct. 21, 2011 (DE) 10 2011 085 030.9
Feb. 16, 2012 (DE) 10 2012 202 377.1

(51) Int. Cl. H01L 23/29; C09J 7/02; C09J 153/00

(52) U.S. Cl. CPC H01L 23/293; C09J 153/00; C09J 7/0221; C09J 2203/326; C09J 2453/00
USPC 428/339; 522/109; 428/355 EP; 427/58

(57) ABSTRACT

An adhesive and method for encapsulating an electronic arrangement with respect to permeants, wherein the adhesive and method have (a) at least one copolymer comprising at least isobutylene or butylene as comonomer kind and at least one comonomer kind which, considered as hypothetical homopolymer, has a softening temperature of greater than 40° C., (b) at least one kind of an at least partly hydrogenated tackifier resin, (c) at least one kind of a reactive resin based on cyclic ethers having a softening temperature of less than 40° C., preferably less than 20° C., and (d) at least one kind of a photoinitiator for initiating cationic curing

The present invention relates to an adhesive particularly for encapsulating an electronic arrangement.

(Opto)electronic arrangements are being used with ever-increasing frequency in commercial products or are close to market introduction. Such arrangements comprise organic or inorganic electronic structures, examples being organic, organometallic or polymeric semiconductors or else combinations of these. Depending on the desired application, these arrangements and products are rigid or flexible in form, there being an increasing demand for flexible arrangements. Arrangements of this kind are produced, for example, by printing techniques, such as relief, gravure, screen or planographic printing, or else what is called “non-impact printing”, such as, for instance, thermal transfer printing, inkjet printing or digital printing. In many cases, however, vacuum techniques are used as well, such as chemical vapour deposition (CVD), physical vapour deposition (PVD), plasma-enhanced chemical or physical deposition techniques (PECVD), sputtering, (plasma) etching or vapour coating, with patterning taking place generally through masks.

Examples of (opto)electronic applications that are already commercial or are of interest in terms of their market potential include electrophoretic or electrochromic constructions or displays, organic or polymeric light-emitting diodes (OLEDs or PLEDs) in readout and display devices, or as illumination, electroluminescent lamps, light-emitting electrochemical cells (LEECs), organic solar cells, preferably dye or polymer solar cells, inorganic solar cells, preferably thin-film solar cells, more particularly those based on silicon, germanium, copper, indium and/or selenium, organic field-effect transistors, organic switching elements, organic optical amplifiers, organic laser diodes, organic or inorganic sensors or else organic- or inorganic-based RFID transponders.

A perceived technical challenge for realization of sufficient lifetime and function of (opto)electronic arrangements in the area of organic and/or inorganic (opto)electronics, especially in the area of organic (opto)electronics, is the protection of the components they contain against permeants. Permeants may be a large number of low molecular mass organic or inorganic compounds, more particularly water vapour and oxygen.

A large number of (opto)electronic arrangements in the area of organic and/or inorganic (opto)electronics, especially where organic raw materials are used, are sensitive not only to water vapour but also to oxygen, and for many arrangements the penetration of water vapour is classed as a relatively severe problem. During the lifetime of the electronic arrangement, therefore, it requires protection by means of encapsulation, since otherwise the performance drops off over the period of application. For example, oxidation of the components, in the case of light-emitting arrangements such as electroluminescent lamps (EL lamps) or organic light-emitting diodes (OLEDs) for instance, may drastically reduce the luminosity, the contrast in the case of electrophoretic displays (EP displays), or the efficiency in the case of solar cells, within a very short time.

In organic and/or inorganic (opto)electronics, particularly in the case of organic (opto)electronics, there is a particular need for flexible bonding solutions which constitute a permeation barrier to permeants, such as oxygen and/or water vapour. In addition there are a host of further requirements for such (opto)electronic arrangements. The flexible bonding solutions are therefore intended not only to achieve effective adhesion between two substrates, but also, in addition, to fulfil properties such as high shear strength and peel strength, chemical stability, ageing resistance, high transparency, ease of processing, and also high flexibility and pliability.

One approach common in the prior art, therefore, is to place the electronic arrangement between two substrates that are impermeable to water vapour and oxygen. This is then followed by sealing at the edges. For non-flexible constructions, glass or metal substrates are used, which offer a high permeation barrier but are very susceptible to mechanical loads. Furthermore, these substrates give rise to a relatively high thickness of the arrangement as a whole. In the case of metal substrates, moreover, there is no transparency. For flexible arrangements, in contrast, sheetlike substrates are used, such as transparent or non-transparent films, which may have a multi-ply configuration. In this case it is possible to use not only combinations of different polymers, but also organic or inorganic layers. The use of such sheetlike substrates allows a flexible, extremely thin construction. For the different applications there are a very wide variety of possible substrates, such as films, wovens, nonwovens and papers or combinations thereof, for example.

In order to obtain the most effective sealing, specific barrier adhesives are used. A good adhesive for the sealing of (opto)electronic components has a low permeability for oxygen and particularly for water vapour, has sufficient adhesion to the arrangement, and is able to flow well onto the arrangement. Owing to incomplete wetting of the surface of the arrangement and owing to pores that remain, low capacity for flow on the arrangement may reduce the barrier effect at the interface, since it permits lateral ingress of oxygen and water vapour independently of the properties of the adhesive. Only if the contact between adhesive and substrate is continuous are the properties of the adhesive the determining factor for the barrier effect of the adhesive.

For the purpose of characterizing the barrier effect it is usual to state the oxygen transmission rate OTR and the water vapour transmission rate WVTR. Each of these rates indicates the flow of oxygen or water vapour, respectively, through a film per unit area and unit time, under specific conditions of temperature and partial pressure and also, optionally, further measurement conditions such as relative atmospheric humidity. The lower the values the more suitable the respective material for encapsulation. The statement of the permeation is not based solely on the values of WVTR or OTR, but instead also always includes an indication of the average path length of the permeation, such as the thickness of the material, for example, or a standardization to a particular path length.

The permeability P is a measure of the perviousness of a body for gases and/or liquids. A low P values denotes a good barrier effect. The permeability P is a specific value for a defined material and a defined permeant under steady-state conditions and with defined permeation path length, partial pressure and temperature. The permeability P is the product of diffusion term D and solubility term S:

P=D*S

The solubility term S describes in the present case the affinity of the barrier adhesive for the permeant. In the case of water vapour, for example, a low value for S is achieved by hydrophobic materials. The diffusion term D is a measure of the mobility of the permeant in the barrier material, and is directly dependent on properties, such as the molecular mobility or the free volume. Often, in the case of highly crosslinked or highly crystalline materials, relatively low values are obtained for D. Highly crystalline materials, however, are generally less transparent, and greater crosslinking results in a lower flexibility. The permeability P typically rises with an increase in the molecular mobility, as for instance when the temperature is raised or the glass transition point is exceeded.

A low solubility term S is usually insufficient for achieving good barrier properties. One classic example of this, in particular, are siloxane elastomers. The materials are extraordinarily hydrophobic (low solubility term), but as a result of their freely rotatable Si-O bond (large diffusion term) have a comparatively low barrier effect for water vapour and oxygen. For a good barrier effect, then, a good balance between solubility term S and diffusion term D is necessary.

Approaches at increasing the barrier effect of an adhesive must take account of the two parameters D and S, with a view in particular to their influence on the permeability of water vapour and oxygen. In addition to these chemical properties, thought must also be given to consequences of physical effects on the permeability, particularly the average permeation path length and interface properties (flow-on behaviour of the adhesive, adhesion). The ideal barrier adhesive has low D values and S values in conjunction with very good adhesion to the substrate.

For this purpose use has hitherto been made in particular of liquid adhesives and adhesives based on epoxides (WO 98/21287 A1; U.S. Pat. No. 4,051,195 A; U.S. Pat. No. 4,552,604 A). As a result of a high degree of crosslinking, these adhesives have a low diffusion term D. Their principal field of use is in the edge bonding of rigid arrangements, but also moderately flexible arrangements. Curing takes place thermally or by means of UV radiation. Full-area bonding is hard to achieve, owing to the contraction that occurs as a result of curing, since in the course of curing there are stresses between adhesive and substrate that may in turn lead to delamination.

Using these liquid adhesives harbours a series of disadvantages. For instance, low molecular mass constituents (VOCs—volatile organic compounds) may damage the sensitive electronic structures in the arrangement and may hinder production operations. The adhesive must be applied, laboriously, to each individual constituent of the arrangement. The acquisition of expensive dispensers and fixing devices is necessary in order to ensure precise positioning. Moreover, the nature of application prevents a rapid continuous operation, and the laminating step that is subsequently needed may also make it more difficult, owing to the low viscosity, to achieve a defined layer thickness and bond width within narrow limits.

Furthermore, the residual flexibility of such highly crosslinked adhesives after curing is low. In the low temperature range or in the case of 2-component systems, the use of thermally crosslinking systems is limited by the potlife, in other words the processing life until gelling has taken place. In the high temperature range, and particularly in the case of long reaction times, in turn, the sensitive (opto)electronic structures limit the possibility of using such systems—the maximum temperatures that can be employed in the case of (opto)electronic structures are often 60° C., since above even this temperature there may be initial damage. Flexible arrangements which comprise organic electronics and are encapsulated using transparent polymer films or assemblies of polymer films and inorganic layers, in particular, have narrow limits here. The same applies to laminating steps under high pressure. In order to achieve improved durability, it is advantageous here to forgo a temperature loading step and to carry out lamination under a relatively low pressure.

As an alternative to the thermally curable liquid adhesives, radiation-curing adhesives as well are now used in many cases (US 2004/0225025 A1). The use of radiation-curing adhesives prevents long-lasting thermal load on the electronic arrangement.

Particularly if the (opto)electronic arrangements are to be flexible, it is important that the adhesive used is not too rigid and brittle. Accordingly, pressure-sensitive adhesives (PSAs) and heat-activatedly bondable adhesive sheets are particularly suitable for such bonding. In order to flow well onto the substrate but at the same time to attain a high bonding strength, the adhesives ought initially to be very soft, but then to be able to be crosslinked. As crosslinking mechanisms it is possible, depending on the chemical basis of the adhesive, to implement thermal cures and/or radiation cures. While thermal curing is very slow, radiation cures can be initiated within a few seconds. Accordingly, radiation cures, more particularly UV curing, are preferred, especially in the case of continuous production processes.

DE 10 2008 060 113 A1 describes a method for encapsulating an electronic arrangement with respect to permeants, using a PSA based on butylene block copolymers, more particularly isobutylene block copolymers, and describes the use of such an adhesive in an encapsulation method. In combination with the elastomers, defined resins, characterized by DACP and MMAP values, are preferred. The adhesive, moreover, is preferably transparent and may exhibit UV-blocking properties. As barrier properties, the adhesive preferably has a WVTR of <40 g/m^{2*}d and an OTR of <5000 g/m^{2*}d bar. In the method, the PSA may be heated during and/or after application. The PSA may be crosslinked—by radiation, for example. Classes of substance are proposed via which such crosslinking can be advantageously performed. However, no specific examples are given that lead to particularly low volume permeation and interfacial permeation in conjunction with high transparency and flexibility.

EP 1 518 912 A1 teaches an adhesive for encapsulating an electroluminescent element which comprises a photocationically curable compound and a photocationic initiator. Curing takes place as a dark reaction following light stimulation. The adhesive is preferably epoxy-based. Aliphatic hydroxides and polyethers may be added as co-crosslinking components. Moreover, a tackifier resin may be present in order to adjust adhesion and cohesion. This may also include polyisobutylene. No specific information is given regarding the compatibility of the individual constituents, and there are also no indications of the molar masses of the polymers.

JP 4,475,084 B1 teaches transparent sealants for organic electroluminescent elements, that may be based on block copolymer. Examples listed are SIS and SBS and also the hydrogenated versions. Not specified, however, are constituents which permit crosslinking after application. Nor are the barrier properties of the sealants addressed. The sealing layer apparently does not take on any specific barrier function.

US 2006/100299 A1 discloses a PSA which comprises a polymer having a softening temperature, as defined in US 2006/100299 A1, of greater than +60° C., a polymerizable resin having a softening temperature, as defined in US 2006/100299 A1 of less than +30° C., and an initiator which is able to lead to a reaction between resin and polymer. Reactively equipped polymers, however, are not available universally, and so there are restrictions on the selection of this polymer basis when other properties and costs are an issue. Moreover, any kind of functionalization (for the purpose of providing reactivity) is accompanied by an increase in basic polarity and hence by an unwanted rise in water vapour permeability. No copolymers based on isobutylene or butylene are identified, and no information is given on molar masses of the polymers.

US 2009/026934 A1 describes layers of adhesive for the encapsulation of organic electroluminescent elements. The adhesives comprise polyisobutylene and a hydrogenated hydrocarbon resin. For crosslinking after application it is possible to use various reactive resins, including epoxides. WVTR values in the examples are typically between 5 and 20 g/m^{2*}d. OTR values are not stated. As copolymer it is possible to utilize polyisobutylene polymers, generated by copolymerization with other soft monomers. The molar masses of the polymers are typically >500 000 g/mol.

WO 2008/144080 A1 teaches constructions with sensitive organic layers that are encapsulated. Encapsulation takes place by a cured elastomeric laminating adhesive. Adhesives employed are mixtures of reactive oligomers and/or polymers and reactive monomers. Curing may be accomplished via radiation or heat. The reactivity, according to the description, is introduced via (meth)acrylate groups. Cationic curing of epoxy resins is not mentioned explicitly. Copolymers as an elastomer basis are not specified, and nor is any information given concerning molar masses of the polymers.

US 2010/0137530 A1 discloses curable adhesive layers based on epoxy resin mixtures. One kind of epoxy resin has a low molar mass, another kind a relatively high molar mass. Cationic curing is carried out, initiated by UV. No elastomer base is provided.

It is an object of the invention to provide an adhesive which is able to prevent the harmful influence of oxygen and water vapour on sensitive functional layers such as, for example, in the area of organic photoelectric cells for solar modules, or in the area of organic light-emitting diodes (OLEDs), by means of a good barrier effect with respect to the harmful substances; which is able to join different components of the functional elements to one another; which is readily manageable in adhesive bonding operations; which allows a flexible and tidy processing; and which is nevertheless easy to use for the producer.

This object is achieved by means of an adhesive as characterized in more detail in the main claim. The dependent claims describe advantageous embodiments of the invention. Also encompassed is the use of the adhesive of the invention.

The invention accordingly provides an adhesive, preferably a pressure-sensitive adhesive, comprising
(a) at least one copolymer comprising at least isobutylene or butylene as comonomer kind and at least one comonomer kind which—considered as hypothetical homopolymer—has a softening temperature of greater than 40° C.,
(b) at least one kind of an at least partly hydrogenated tackifier resin,
(c) at least one kind of a reactive resin based on a cyclic ether having a softening temperature of less than 40° C., preferably of less than 20° C.,
(d) at least one kind of a photoinitiator for initiating cationic curing.

In the case of amorphous substances, the softening temperature here corresponds to the glass transition temperature; in the case of (semi-)crystalline substances, the softening temperature here corresponds to the melting temperature.

In the adhesives sector, pressure-sensitive adhesives (PSAs) are notable in particular for their permanent tack and flexibility. A material which exhibits permanent pressure-sensitive tack must at any given point in time feature a suitable combination of adhesive and cohesive properties. For good adhesion properties it is necessary to formulate PSAs for an optimum balance between adhesive and cohesive properties.

The adhesive is preferably a PSA, in other words a viscoelastic mass which remains permanently tacky and adhesive in the dry state at room temperature. Bonding is accomplished by gentle applied pressure, immediately, to virtually every substrate.

According to one preferred embodiment of the invention, the copolymer or copolymers is or are random, alternating, block, star and/or graft copolymers having a molar mass M_{W} (weight average) of 300 000 g/mol or less, preferably 200 000 g/mol or less. Smaller molar weights are preferred here on account of their better processing qualities.

Copolymers used are, for example, random copolymers of at least two different monomer kinds, of which at least one is isobutylene or butylene and at least one other is a comonomer having—viewed as hypothetical homopolymer—a softening temperature of greater than 40° C. Advantageous examples of this second comonomer kind are vinylaromatics (including partly or fully hydrogenated versions), methyl methacrylate, cyclohexyl methacrylate, isobornyl methacrylate and isobornyl acrylate.

Particularly preferred examples are styrene and a-methylstyrene, with this enumeration making no claim to completeness.

With further preference, the copolymer or copolymers is or are block, star and/or graft copolymers which contain at least one kind of first polymer block (“soft block”) having a softening temperature of less than −20° C. and at least one kind of a second polymer block (“hard block”) having a softening temperature of greater than +40° C.

The soft block here is preferably apolar in construction and preferably comprises butylene or isobutylene as homopolymer block or copolymer block, the latter preferably copolymerized with itself or with one another or with further comonomers, more preferably apolar comonomers. Examples of suitable apolar comonomers are (partly) hydrogenated polybutadiene, (partly) hydrogenated polyisoprene and/or polyolefins.

The hard block is preferably constructed from vinylaromatics (including partly or fully hydrogenated versions), methyl methacrylate, cyclohexyl methacrylate, isobornyl methacrylate and/or isobornyl acrylate. Particularly preferred examples are styrene and a-methylstyrene, this enumeration making no claim to completeness. The hard block thus comprises the at least one comonomer kind which—viewed as hypothetical homopolymer—has a softening temperature of greater than 40° C.

In one particularly advantageous embodiment, the preferred soft blocks and hard blocks described are actualized simultaneously in the copolymer or copolymers.

It is advantageous if the at least one block copolymer is a triblock copolymer constructed from two terminal hard blocks and one middle soft block. Diblock copolymers are likewise highly suitable, as are mixtures of triblock and diblock copolymers.

It is very preferred to use triblock copolymers of the polystyrene-block-polyisobutylene-block-polystyrene type. Systems of this kind have been disclosed under the names SIBStar from Kaneka and Oppanol IBS from BASF. Other systems which can be used advantageously are described in EP 1 743 928 A1.

The fact that the copolymers include a fraction of isobutylene or butylene as at least one comonomer kind results in an apolar adhesive which offers advantageously low volume barrier properties especially with respect to water vapour.

The low molar masses of the copolymers, in contrast to the prior art, permit good processing properties for the producer, especially in formulating and coating operations. Low molar mass leads to better and faster solubility, if solvent-based operations are desired (for isobutylene polymers and butylene polymers particularly, the selection of suitable solvents is small). Moreover, higher copolymer concentrations in the solution are possible. In solvent-free operations as well, an inventively low molar mass proves to be an advantage, since the melt viscosity is lower than with comparative systems of higher molar mass.

Merely reducing the molar mass does lead, of course, to better solubility and lower solution and melt viscosities. However, with the lower molar mass, there is detriment to other properties important from a performance standpoint, such as the cohesion of an adhesive, for example. Here, the inventive use of the at least second comonomer kind, with the softening temperature, for a hypothetical homopolymer, of more than 40° C., is an effective counter.

The adhesive of the invention comprises at least one kind of an at least partly hydrogenated tackifier resin, advantageously of the sort which are compatible with the copolymer or, where a copolymer constructed from hard blocks and soft blocks is used, compatible primarily with the soft block (soft resins).

It is advantageous if this tackifier resin has a tackifier resin softening temperature of greater than 25° C. It is advantageous, furthermore, if additionally at least one kind of tackifier resin having a tackifier resin softening temperature of less than 20° C. is used. In this way it is possible, if necessary, to fine-tune not only the technical bonding behaviour but also the flow behaviour on the bonding substrate.

Resins in the PSA may be, for example, partially or fully hydrogenated resins based on rosin and rosin derivatives, hydrogenated polymers of dicyclopentadiene, partially, selectively or fully hydrogenated hydrocarbon resins based on C₅, C₅/C₉ or C₉ monomer streams, polyterpene resins based on a-pinene and/or R-pinene and/or δ-limonene, and hydrogenated polymers of preferably pure C₈ and C₉ aromatics. Aforementioned tackifier resins may be used either alone or in a mixture.

It is possible here to use both room-temperature-solid resins and liquid resins. In order to ensure high ageing stability and UV stability, hydrogenated resins with a degree of hydrogenation of at least 90%, preferably of at least 95%, are preferred.

Preference is given, furthermore, to apolar resins having a DACP (diacetone alcohol cloud point) of more than 30° C. and an MMAP (mixed methylcylohexane aniline point) of greater than 50° C., more particularly having a DACP of more than 37° C. and an MMAP of greater than 60° C. The DACP and the MMAP each indicate the solubility in a particular solvent. Through the selection of these ranges, the resulting permeation barrier, especially with respect to water vapour, is particularly high.

The adhesive of the invention further comprises at least one kind of a reactive resin based on a cyclic ether, for radiation crosslinking and optionally thermal crosslinking, having a softening temperature of less than 40° C., preferably of less than 20° C.

The reactive resins based on cyclic ethers are more particularly epoxides, i.e. compounds which carry at least one oxirane group, or oxetanes. They may be aromatic or more particularly aliphatic or cycloaliphatic in nature.

Reactive resins that can be used may be monofunctional, difunctional, trifunctional, tetrafunctional or of higher functionality up to polyfunctional, where the functionality relates to the cyclic ether group.

Examples, without any intention to impose a restriction, are 3,4-epoxycyclohexylmethyl 3′,4′-epoxycyclohexanecarboxylate (EEC) and derivatives, dicyclopentadiene dioxide and derivatives, 3-ethyl-3-oxetanemethanol and derivatives, diglycidyl tetrahydrophthalate and derivatives, diglycidyl hexahydrophthalate and derivatives, 1,2-ethane diglycidyl ether and derivatives, 1,3-propane diglycidyl ether and derivatives, 1,4-butanediol diglycidyl ether and derivatives, higher 1,n-alkane diglycidyl ethers and derivatives, bis[(3,4-epoxycyclohexyl)methyl] adipate and derivatives, vinylcyclohexyl dioxide and derivatives, 1,4-cyclohexanedimethanol bis(3,4-epoxycyclohexanecarboxylate) and derivatives, diglycidyl 4,5-epoxytetrahydrophthalate and derivatives, bis[1-ethyl(3-oxetanyl)methyl] ether and derivatives, pentaerythrityl tetraglycidyl ether and derivatives, bisphenol A diglycidyl ether (DGEBA), hydrogenated bisphenol A diglycidyl ether, bisphenol F diglycidyl ether, hydrogenated bisphenol F diglycidyl ether, epoxyphenol novolaks, hydrogenated epoxyphenol novolaks, epoxycresol novolaks, hydrogenated epoxycresol novolaks, 2-(7-oxabicyclospiro(1,3-dioxane-5,3′-(7-oxabicyclo[4.1.0]heptane)), 1,4-bis((2,3-epoxypropoxy)-methyl)cyclohexane.

Reactive resins can be used in their monomeric form or else dimeric form, trimeric form, etc., up to and including their oligomeric form.

Mixtures of reactive resins with one another, but also with other coreactive compounds such as alcohols (monofunctional or polyfunctional) or vinyl ethers (monofunctional or polyfunctional) are likewise possible.

The adhesive formulation additionally comprises at least one kind of photoinitiator for the cationic curing of the reactive resins. Among the initiators for cationic UV curing, more particularly, sulphonium-, iodonium- and metallocene-based systems are usable.

As examples of sulphonium-based cations, reference is made to the details in U.S. Pat. No. 6,908,722 B1 (especially columns 10 to 21).

Examples of anions which serve as counterions to the abovementioned cations include tetrafluoroborate, tetraphenylborate, hexafluorophosphate, perchlorate, tetrachloroferrate, hexafluoroarsenate, hexafluoroantimonate, pentafluorohydroxyantimonate, hexachloro-antimonate, tetrakispentafluorophenylborate, tetrakis(pentafluoromethylphenyl)borate, bi(trifluoromethylsulphonyl)amide and tris(trifluoromethylsulphonyl)methide. Additionally conceivable as anions, especially for iodonium-based initiators, are also chloride, bromide or iodide, although preference is given to initiators essentially free of chlorine and bromine.

More specifically, the usable systems include
sulphonium salts (see, for example, U.S. Pat. No. 4,231,951 A, U.S. Pat. No. 4,256,828 A, U.S. Pat. No. 4,058,401 A, U.S. Pat. No. 4,138,255 A and US 2010/063221 A1) such as triphenylsulphonium hexafluoroarsenate, triphenylsulphonium hexafluoroborate, triphenylsulphonium tetrafluoroborate, triphenylsulphonium tetrakis(pentafluorobenzyl)borate, methyldiphenylsulphonium tetrafluoroborate, methyldiphenylsulphonium tetrakis(pentafluorobenzyl)borate, dimethylphenylsulphonium hexafluorophosphate, triphenylsulphonium hexafluorophosphate, triphenylsulphonium hexafluoroantimonate, diphenylnaphthylsulphonium hexafluoroarsenate, tritolylsulphonium hexafluorophosphate, anisyldiphenylsulphonium hexafluoroantimonate, 4-butoxyphenyldiphenylsulphonium tetrafluoroborate, 4-butoxyphenyldiphenylsulphonium tetrakis(pentafluorobenzyl)borate, 4-chlorophenyldiphenylsulphonium hexafluoroantimonate, tris(4-phenoxyphenyl)-sulphonium hexafluorophosphate, di(4-ethoxyphenyl)methylsulphonium hexafluoroarsenate, 4-acetylphenyldiphenylsulphonium tetrafluoroborate, 4-acetylphenyldiphenylsulphonium tetrakis(pentafluorobenzyl)borate, tris(4-thiomethoxyphenyl)sulphonium hexafluorophosphate, di(methoxysulphonylphenyl)-methylsulphonium hexafluoroantimonate, di(methoxynaphthyl)methylsulphonium tetrafluoroborate, di(methoxynaphthyl)methylsulphonium tetrakis(pentafluorobenzyl)-borate, di(carbomethoxyphenyl)methylsulphonium hexafluorophosphate, (4-octyloxyphenyl)diphenylsulphonium tetrakis(3,5-bis(trifluoromethyl)phenyl)borate, tris[4-(4-acetylphenyl)thiophenyl]sulphonium tetrakis(pentafluorophenyl)borate, tris(dodecylphenyl)sulphonium tetrakis(3,5-bis(trifluoromethyl)phenyl)borate, 4-acetamidophenyldiphenylsulphonium tetrafluoroborate, 4-acetamidophenyldiphenyl-sulphonium tetrakis(pentafluorobenzyl)borate, dimethylnaphthylsulphonium hexafluorophosphate, trifluoromethyldiphenylsulphonium tetrafluoroborate, trifluoromethyldiphenylsulphonium tetrakis(pentafluorobenzyl)borate, phenylmethyl-benzylsulphonium hexafluorophosphate, 5-methylthianthrenium hexafluorophosphate, 10-phenyl-9,9-dimethylthioxanthenium hexafluorophosphate, 10-phenyl-9-oxothioxanthenium tetrafluoroborate, 10-phenyl-9-oxothioxanthenium tetrakis(penta-fluorobenzyl)borate, 5-methyl-10-oxothianthrenium tetrafluoroborate, 5-methyl-10-oxothianthrenium tetrakis(pentafluorobenzyl)borate and 5-methyl-10,10-dioxothianthrenium hexafluorophosphate,
iodonium salts (see, for example, U.S. Pat. No. 3,729,313 A, U.S. Pat. No. 3,741,769 A, U.S. Pat. No. 4,250,053 A, U.S. Pat. No. 4,394,403 A and US 2010/063221 A1) such as diphenyliodonium tetrafluoroborate, di(4-methylphenyl)iodonium tetrafluoroborate, phenyl-4-methylphenyliodonium tetrafluoroborate, di(4-chlorophenyl)iodonium hexafluorophosphate, dinaphthyliodonium tetrafluoroborate, di(4-trifluoromethylphenyl)iodonium tetrafluoroborate, diphenyliodonium hexafluorophosphate, di(4-methylphenyl)iodonium hexafluorophosphate, diphenyliodonium hexafluoroarsenate, di(4-phenoxyphenyl)iodonium tetrafluoroborate, phenyl-2-thienyliodonium hexafluorophosphate, 3,5-dimethyl-pyrazolyl-4-phenyliodonium hexafluorophosphate, diphenyliodonium hexafluoroantimonate, 2,2′-diphenyliodonium tetrafluoroborate, di(2,4-dichlorophenyl) iodonium hexafluorophosphate, di(4-bromophenyl)iodonium hexafluorophosphate, di(4-methoxyphenyl)iodonium hexafluorophosphate, di(3-carboxyphenyl)iodonium hexafluorophosphate, di(3-methoxycarbonylphenyl)iodonium hexafluorophosphate, di(3-methoxysulphonylphenyl)-iodonium hexafluorophosphate, di(4-acetamidophenyl)iodonium hexafluorophosphate, di(2-benzothienyl)iodonium hexafluorophosphate, diaryliodonium tristrifluoromethylsulphonylmethide such as diphenyliodonium hexafluoroantimonate, diaryliodonium tetrakis(pentafluorophenyl)borate such as diphenyliodonium tetrakis-(pentafluorophenyl)borate, (4-n-desiloxyphenyl)phenyliodonium hexafluoro-antimonate, [4-(2-hydroxy-n-tetradesiloxy)phenyl]phenyliodonium hexafluoro-antimonate, [4-(2-hydroxy-n-tetradesiloxy)phenyl]phenyliodonium trifluorosulphonate, [4-(2-hydroxy-n-tetradesiloxy)phenyl]phenyliodonium hexafluorophosphate, [4-(2-hydroxy-n-tetradesiloxy)phenyl]phenyliodonium tetrakis(pentafluorophenyl)borate, bis(4-tert-butylphenyl)iodonium hexafluoroantimonate, bis(4-tert-butylphenyl)iodonium hexafluorophosphate, bis(4-tert-butylphenyl)iodonium trifluorosulphonate, bis(4-tert-butylphenyl)iodonium tetrafluoroborate, bis(dodecylphenyl) iodonium hexafluoroantimonate, bis(dodecylphenyl)iodonium tetrafluoroborate, bis(dodecylphenyl)iodonium hexafluorophosphate, bis(dodecylphenyl)iodonium trifluoromethylsulphonate, di(dodecylphenyl)iodonium hexafluoroantimonate, di(dodecylphenyl)iodonium triflate, diphenyliodonium bisulphate, 4,4′-dichlorodiphenyliodonium bisulphate, 4,4′-dibromodiphenyliodonium bisulphate, 3,3′-dinitrodiphenyliodonium bisulphate, 4,4′-dimethyldiphenyliodonium bisulphate, 4,4′-bis(succinimidodiphenyl)iodonium bisulphate, 3-nitrodiphenyliodonium bisulphate, 4,4′-dimethoxy-diphenyliodonium bisulphate, bis(dodecylphenyl)iodonium tetrakis(pentafluorophenyl)borate, (4-octyloxyphenyl)phenyliodonium tetrakis(3,5-bis-trifluoromethylphenyl)borate and (tolylcumyl)iodonium tetrakis(pentafluorophenyl)borate, and
ferrocenium salts (see, for example, EP 542 716 B1) such as η⁵-(2,4-cyclopentadien-l-yl)-[(1,2,3,4,5,6,9)-(1-methylethyl)benzene]iron.

Examples of commercialized photoinitiators are Cyracure UVI-6990, Cyracure UVI-6992, Cyracure UVI-6974 and Cyracure UVI-6976 from Union Carbide, Optomer SP-55, Optomer SP-150, Optomer SP-151, Optomer SP-170 and Optomer SP-172 from Adeka, San-Aid SI-45L, San-Aid SI-60L, San-Aid SI-80L, San-Aid SI-100L, San-Aid SI-110L, San-Aid SI-150L and San-Aid SI-180L from Sanshin Chemical, SarCat CD-1010, SarCat CD-1011 and SarCat CD-1012 from Sartomer, Degacure K185 from Degussa, Rhodorsil Photoinitiator 2074 from Rhodia, CI-2481, CI-2624, CI-2639, CI-2064, CI-2734, CI-2855, CI-2823 and CI-2758 from Nippon Soda, Omnicat 320, Omnicat 430, Omnicat 432, Omnicat 440, Omnicat 445, Omnicat 550, Omnicat 550 BL and Omnicat 650 from IGM Resins, Daicat II from Daicel, UVAC 1591 from Daicel-Cytec, FFC 509 from 3M, BBI-102, BBI-103, BBI-105, BBI-106, BBI-109, BBI-110, BBI-201, BBI, 301, BI-105, DPI-105, DPI-106, DPI-109, DPI-201, DTS-102, DTS-103, DTS-105, NDS-103, NDS-105, NDS-155, NDS-159, NDS-165, TPS-102, TPS-103, TPS-105, TPS-106, TPS-109, TPS-1000, MDS-103, MDS-105, MDS-109, MDS-205, MPI-103, MPI-105, MPI-106, MPI-109, DS-100, DS-101, MBZ-101, MBZ-201, MBZ-301, NAI-100, NAI-101, NAI-105, NAI-106, NAI-109, NAI-1002, NAI-1003, NAI-1004, NB-101, NB-201, NDI-101, NDI-105, NDI-106, NDI-109, PAI-01, PAI-101, PAI-106, PAI-1001, PI-105, PI-106, PI-109, PYR-100, SI-101, SI-105, SI-106 and SI-109 from Midori Kagaku, Kayacure PCI-204, Kayacure PCI-205, Kayacure PCI-615, Kayacure PCI- 625, Kayarad 220 and Kayarad 620, PCI-061 T, PCI-062T, PCI-020T, PCI-022T from Nippon Kayaku, TS-01 and TS-91 from Sanwa Chemical, Deuteron UV 1240 from Deuteron, Tego Photocompound 1465N from Evonik, UV 9380 C-D1 from GE Bayer Silicones, FX 512 from Cytec, Silicolease UV Cata 211 from Bluestar Silicones and Irgacure 250, Irgacure 261, Irgacure 270, Irgacure PAG 103, Irgacure PAG 121, Irgacure PAG 203, Irgacure PAG 290, Irgacure CGI 725, Irgacure CGI 1380, Irgacure CGI 1907 and Irgacure GSID 26-1 from BASF.

The person skilled in the art is aware of further systems that can likewise be employed in accordance with the invention. Photoinitiators are employed uncombined or as a combination of two or more photoinitiators.

Advantageous photoinitiators are those which exhibit absorption at less than 350 nm and advantageously at greater than 250 nm. Initiators which absorb above 350 nm, in the violet light range, for example, can likewise be employed. Sulphonium-based photoinitiators are employed with particular preference, since they have advantageous UV absorption characteristics.

In addition, it is possible to employ photosensitizers which reduce the photoinitiator in a redox process. In this process, the actual photoinitiator is broken down, forming reactive cations that can start a cationic polymerization. This method of conducting the reaction allows initiation of the cationic polymerization at higher wavelengths. Examples of such photosensitizers are diphenolmethanone and derivatives, acetophenone derivatives, for example Irgacure 651, anthracene derivatives such as 2-ethyl-9,10-dimethoxyanthracene and 9-hydroxymethylanthracene, phenyl ketone derivatives such as 1-hydroxycyclohexyl phenyl ketone, 2-hydroxy-2-methyl-1-phenylpropan-1-one and 4-(2-hydroxyethoxy)phenyl 2-hydroxy-2-methylpropyl ketone (Irgacure 184, Darocure 1173, Irgacure 2959), and thioxanthenone derivatives such as 4-isopropyl-9-thioxanthenone or 1-chloro-4-propoxythioxanthenone.

Particularly preferred combinations of photoinitiator and sensitizer take into account the different redox potentials and retardation potentials of intermediates, as is the case for combinations of diaryliodonium-based photoinitiators with acetophenone sensitizers, and as described in Bulut U., Crivello J. V., J. Polym. Sci. 2005, 43, 3205-3220.

The PSA is preferably partly crosslinked or crosslinked to completion only after application, on the electronic arrangement.

The adhesive may have customary adjuvants added, such as ageing inhibitors (antiozonants, antioxidants, light stabilizers, etc.).

Additives for the adhesive that are typically utilized are as follows:
plasticizers such as, for example, plasticizer oils or low molecular mass liquid polymers such as, for example, low molecular mass polybutenes
primary antioxidants such as, for example, sterically hindered phenols
secondary antioxidants such as, for example, phosphites or thioethers
process stabilizers such as, for example, C radical scavengers
light stabilizers such as, for example, UV absorbers or sterically hindered amines
processing assistants
wetting additives
adhesion promoters
endblock reinforcer resins and/or
optionally further polymers, preferably elastomeric in nature; elastomers which can be utilized accordingly include, among others, those based on pure hydrocarbons, examples being unsaturated polydienes such as natural or synthetically produced polyisoprene or polybutadiene, elastomers with substantial chemical saturation, such as, for example, saturated ethylene-propylene copolymers, a-olefin copolymers, polyisobutylene, butyl rubber, ethylene-propylene rubber, and also chemically functionalized hydrocarbons such as, for example, halogen-containing, acrylate-containing, allyl ether-containing or vinyl ether-containing polyolefins.

The adjuvants or additives are not mandatory; the adhesive also works without their addition, individually or in any desired combination.

Fillers can be used advantageously in the PSAs of the invention. As fillers in the adhesive it is preferred to use nanoscale and/or transparent fillers. In the present context a filler is termed nanoscale if in at least one dimension it has a maximum extent of about 100 nm, preferably about 10 nm. Particular preference is given to using those fillers which are transparent in the adhesive and have a platelet-shaped crystallite structure and a high aspect ratio with homogeneous distribution. The fillers with a platelet-like crystallite structure and with aspect ratios of well above 100 generally have a thickness of only a few nm, but the length and/or width of the crystallites may be up to several μm. Fillers of this kind are likewise referred to as nanoparticles. The particulate architecture of the fillers with small dimensions, moreover, is particularly advantageous for a transparent embodiment of the PSA.

Through the construction of labyrinthine structures by means of the fillers described above in the adhesive matrix, the diffusion pathway for, for example, oxygen and water vapour is extended in such a way that their permeation through the layer of adhesive is lessened. For improved dispersibility of these fillers in the binder matrix, these fillers may be surface-modified with organic compounds. The use of such fillers per se is known from US 2007/0135552 A1 and from WO 02/026908 A1, for example.

In another advantageous embodiment of the present invention, use is also made of fillers which are able to interact in a particular way with oxygen and/or water vapour. Water vapour or oxygen penetrating into the (opto)electronic arrangement is then chemically or physically bound to these fillers. These fillers are also referred to as getters, scavengers, desiccants or absorbers. Such fillers include by way of example, but without restriction, the following: oxdizable metals, halides, salts, silicates, oxides, hydroxides, sulphates, sulphites, carbonates of metals and transition metals, perchlorates and activated carbon, including its modifications. Examples are cobalt chloride, calcium chloride, calcium bromide, lithium chloride, zinc chloride, zinc bromide, silicon dioxide (silica gel), aluminium oxide (activated aluminium), calcium sulphate, copper sulphate, sodium dithionite, sodium carbonate, magnesium carbonate, titanium dioxide, bentonite, montmorillonite, diatomaceous earth, zeolites and oxides of alkali metals and alkaline earth metals, such as barium oxide, calcium oxide, iron oxide and magnesium oxide, or else carbon nanotubes. Additionally it is also possible to use organic absorbers, examples being polyolefin copolymers, polyamide copolymers, PET copolyesters or other absorbers based on hybrid polymers, which are used generally in combination with catalysts such as cobalt, for example. Further organic absorbers are, for instance, polyacrylic acid with a low degree of crosslinking, ascorbates, glucose, gallic acid or unsaturated fats and oils.

In order to maximize the activity of the fillers in terms of the barrier effect, their fraction should not be too small. The fraction is preferably at least 5%, more preferably at least 10% and very preferably at least 15% by weight. Typically as high as possible a fraction of fillers is employed, without excessively lowering the bond strengths of the adhesive or adversely affecting other properties. Depending on the type of fillers, filler fractions of more than 40% to 70% by weight may be reached.

Also advantageous is a very fine division and very high surface area on the part of the fillers. This allows a greater efficiency and a higher loading capacity, and is achieved in particular using nanoscale fillers.

The fillers are not mandatory; the adhesive also operates without the addition thereof individually or in any desired combination.

With further preference an adhesive is employed which in certain embodiments is transparent in the visible light of the spectrum (wavelength range from about 400 nm to 800 nm). The desired transparency can be achieved in particular through the use of colourless tackifier resins and by adjusting the compatibility of copolymer (in microphase-separated systems such as block copolymers and graft copolymers, with their soft block) and tackifier resin, but also with the reactive resin. Reactive resins are for this purpose selected advantageously from aliphatic and cycloaliphatic systems. A PSA of this kind is therefore also particularly suitable for full-area use over an (opto)electronic structure. Full-area bonding, in the case of an approximately central disposition of the electronic structure, offers the advantage over edge sealing that the permeant would have to diffuse through the entire area before reaching the structure. The permeation pathway is therefore significantly increased. The prolonged permeation pathways in this embodiment, in comparison to edge sealing by means of liquid adhesives, for instance, have positive consequences for the overall barrier, since the permeation pathway is in inverse proportion to the permeability.

“Transparency” here denotes an average transmittance of the adhesive in the visible range of light of at least 75%, preferably higher than 90%, this consideration being based on uncorrected transmission, in other words without subtracting losses through interfacial reflection.

The adhesive preferably exhibits a haze of less than 5.0%, preferably less than 2.5%.

The PSA may be produced and processed from solution, from dispersion and from the melt. Preference is given to its production and processing from solution or from the melt. Particularly preferred is the manufacture of the adhesive from solution. In that case the constituents of the PSA are dissolved in a suitable solvent, for example toluene or mixtures of mineral spirit and acetone, and the solution is applied to the carrier using techniques that are general knowledge. In the case of processing from the melt, this may involve application techniques via a nozzle or a calender. In the case of processes from solution, coatings with doctorblades, knives, rollers or nozzles are known, to name but a few.

Via the coating temperature it is possible in solvent-free operations to influence the coating outcome. The skilled person is familiar with the operational parameters for obtaining transparent adhesive layers. In solvent coating operations, the coating outcome can be influenced via the selection of the solvent or solvent mixture. Here again, the skilled person is familiar with selection of suitable solvents. Combinations of, in particular, apolar solvents boiling below 100° C. with solvents which boil above 100° C., more particularly aromatic solvents, are very suitable.

Coating from solvents or from the melt is advantageous. For such coating, formulations according to the invention offer great advantages, as has already been stated earlier on above.

The adhesive of the invention can be used with particular advantage in a single-sided or double-sided adhesive tape. This mode of presentation permits particularly simple and uniform application of the adhesive.

The general expression “adhesive tape” encompasses a carrier material which is provided on one or both sides with a (pressure-sensitive) adhesive. The carrier material encompasses all sheetlike structures, examples being two-dimensionally extended films or film sections, tapes with an extended length and limited width, tape sections, diecuts (in the form of edge surrounds or borders of an (opto)electronic arrangement, for example), multi-layer arrangements, and the like. For different applications it is possible to combine a very wide variety of different carriers, such as, for example, films, woven fabrics, nonwovens and papers, with the adhesives. Furthermore, the expression “adhesive tape” also encompasses what are called “adhesive transfer tapes”, i.e. an adhesive tape without carrier. In the case of an adhesive transfer tape, the adhesive is instead applied prior to application between flexible liners which are provided with a release coat and/or have anti-adhesive properties. For application, generally, first one liner is removed, the adhesive is applied, and then the second liner is removed. The adhesive can thus be used directly to join two surfaces in (opto)electronic arrangements. Also possible, however, are adhesive tapes which operate not with two liners, but instead with a single liner with double-sided release. In that case the web of adhesive tape is lined on its top face with one side of a double-sidedly releasing liner, while its bottom face is lined with the reverse side of the double-sidedly releasing liner, more particularly of an adjacent turn in a bale or roll.

As the carrier material of an adhesive tape it is preferred in the present case to use polymer films, film composites, or films or film composites that have been provided with organic and/or inorganic layers. Such films/film composites may be composed of any common plastics used for film manufacture, examples—though without restriction—including the following:
polyethylene, polypropylene—especially the oriented polypropylene (OPP) produced by monoaxial or biaxial stretching, cyclic olefin copolymers (COC), polyvinyl chloride (PVC), polyesters—especially polyethylene terephthalate (PET) and polyethylene naphthalate (PEN), ethylene-vinyl alcohol (EVOH), polyvinylidene chloride (PVDC), polyvinylidene fluoride (PVDF), polyacrylonitrile (PAN), polycarbonate (PC), polyamide (PA), polyethersulphone (PES) or polyimide (PI).

The carrier, moreover, may be combined with organic or inorganic coatings or layers. This can be done by customary techniques, such as surface coating, printing, vapour coating, sputtering, coextruding or laminating, for example. Examples—though without restriction—here include, for instance, oxides or nitrides of silicon and of aluminium, indium-tin oxide (ITO) or sol-gel coatings.

Also very good as carrier films are those made from thin glass. They are available in layer thicknesses of less than 1 mm and even in 30 μm, for example, D 263 T from Schott or Willow Glass from Corning. Thin glass films can be stabilized further by laminating them with a polymeric film (polyester, for example) by means of an adhesive transfer tape, if desired.

Preferred thin glasses used are those having a thickness of 15 to 200 μm, preferably 20 to 100 μm, more preferably 25 to 75, very preferably 30 to 50 μm.

It is advantageous to use a borosilicate glass such as D263 T eco from Schott, an alkali metal-alkaline earth metal-silicate glass or an aluminoborosilicate glass such as AF 32 eco, again from Schott.

An alkali-free thin glass such as AF32 eco is advantageous because the UV transmission is higher. For UV-curing adhesive systems, it is therefore possible to make more effective use of initiators having absorption maxima in the UV-C range, and this increases the stability of the non-crosslinked adhesives with respect to daylight.

An alkali-containing thin glass such as D263 T eco is advantageous because the coefficient of thermal expansion is higher and matches more closely with the polymeric constituents of the further OLED construction. Glasses of these kinds may be produced in a down-draw process, as referenced in

WO 00/41978 A1, or produced in processes of the kind disclosed in EP 1 832 558 A1, for example. WO 00/41978 A1 further discloses processes for producing composites of thin glass and polymer layers or polymer films.

With particular preference, these films/film composites, especially the polymer films, are provided with a permeation barrier for oxygen and water vapour, the permeation barrier exceeding the requirements for the packaging sector (WVTR<10⁻¹ g/(m²d) and OTR<10⁻¹ cm³/(m²d bar)).

In the case of thin glass films or thin glass film composites, no such coating is needed, owing to the intrinsically high barrier properties of the glass.

Thin glass films or thin glass film composites are preferably—as is generally the case for polymer films too—provided in the form of tape from a roll. Corresponding glasses are available already from Corning under the Willow Glass name. This supply form can be laminated outstandingly with an adhesive preferably likewise provided in tape form.

Moreover, the films/film composites, in a preferred embodiment, may be transparent, so that the total construction of an adhesive article of this kind is also transparent. Here again, “transparency” means an average transmittance in the visible region of light of at least 75%, preferably higher than 90%.

In the case of double-sidedly (self-)adhesive tapes, the adhesives used as the top and bottom layer may be identical or different adhesives of the invention, and/or the layer thicknesses thereof that are used may be the same or different. The carrier in this case may have been pretreated according to the prior art on one or both sides, with the achievement, for example, of an improvement in adhesive anchorage. It is also possible for one or both sides to have been furnished with a functional layer which is able to function, for example, as a shutout layer. The layers of PSA may optionally be lined with release papers or release films. Alternatively it is also possible for only one layer of adhesive to be lined with a double-sidedly releasing liner.

In one version, an adhesive of the invention is provided in the double-sidedly (self-)adhesive tape, and also any desired further adhesive is provided, for example one which adheres particularly well to a masking substrate or exhibits particularly good repositionability.

Furthermore, the adhesive and also any adhesive tape formed using it are outstandingly suitable for the encapsulation of an electronic arrangement with respect to permeants, with the adhesive or adhesive tape being applied on and/or around the regions of the electronic arrangement that are to be encapsulated.

Encapsulation in the present case refers not only to complete enclosure with the stated PSA but also even application of the PSA to some of the regions to be encapsulated in the (opto)electronic arrangement: for example, a single-sided coverage or the enframing of an electronic structure.

With adhesive tapes it is possible in principle to carry out two types of encapsulation. Either the adhesive tape is diecut beforehand and bonded only around the regions that are to be encapsulated, or it is adhered by its full area over the regions that are to be encapsulated. An advantage of the second version is the easier operation and the frequently better protection.

The present invention is based first on the finding that in spite of the above-described disadvantages it is possible to use a (pressure-sensitive) adhesive for encapsulating an electronic arrangement, with the disadvantages described above in relation to PSAs occurring not at all or only to a reduced extent. It has been found, in fact, that an adhesive based on a copolymer comprising at least isobutylene or butylene as comonomer kind and at least one comonomer kind which—viewed as a hypothetical homopolymer—has a softening temperature of greater than 40° C. is especially suitable for encapsulating electronic arrangements.

The adhesive preferably being a PSA, application is particularly simple, since there is no need for preliminary fixing. PSAs permit flexible and clean processing. As a result of presentation in the form of a pressure-sensitive adhesive tape, it is also possible to meter easily the amount of the PSA, and there are not any solvent emissions either. At least after application to the target substrate or the target substrates, the PSA is subjected to crosslinking by stimulation of the photoinitiator.

An advantage of the present invention, then, in comparison to other PSAs, is the combination of very good barrier properties with respect to oxygen and especially to water vapour, in conjunction with good interfacial adhesion to different substrates, good cohesive properties and, by comparison with liquid adhesives, very high flexibility and ease of application in the (opto)electronic arrangement and on/in the encapsulation. In certain embodiments, furthermore, there are also highly transparent adhesives that can be used particularly for deployment in (opto)electronic arrangements, since the attenuation of incident or emergent light is kept very low.

Encapsulation by lamination of at least parts of the (opto)electronic constructions with a sheetlike barrier material (e.g. glass, more particularly thin glass, metal oxide-coated films, metallic foils, multilayer substrate materials) can be achieved with a very good barrier effect in a simple roll-to-roll process. The flexibility of the overall construction is dependent not only on the flexibility of the PSA but also on further factors, such as geometry and thickness of the (opto)electronic constructions and/or of the sheetlike barrier materials. The high flexibility of the PSA, however, allows realization of very thin, pliable and flexible (opto)electronic constructions.

Of particular advantage for the encapsulation of (opto)electronic constructions is if they are heated before, during or after the application of the PSA. As a result, the PSA is able to flow on even more effectively, and hence the permeation is reduced further at the interface between the (opto)electronic arrangement and the PSA. The temperature ought preferably to be more than 30° C., more preferably more than 50° C., in order to promote flow accordingly. The temperature, however, should not be selected at too high a level, so as not to damage the (opto)electronic arrangement. The temperature ought as far as possible to be less than 100° C. As an optimum temperature range, temperatures between 50° C. and 70° C. have emerged. It is also advantageous if the PSA is heated additionally or alternatively before, during or after application.

In summary, the adhesive of the invention meets all of the requirements imposed on an adhesive used for encapsulating an (opto)electronic arrangement:
low volume permeation of water vapour and oxygen, as manifested in a WVTR (Mocon) of less than 10 g/m² d, and an OTR (Mocon) of less than 1000 cm³/m²*d*bar,

low interfacial permeation of water vapour and oxygen, as manifested in a WVTR (Ca test) of less than 1 g/m² d and conditional on good flow of the adhesive onto the target substrates;
optional, but preferably high transparency, with a transmittance of preferably more than 90%;
optional, but preferably a haze of less than 5.0%, preferably less than 2.5%;
outstanding lamination properties for example in a roll-to-roll process, as manifested in a bond strength for the non-crosslinked system on glass of more than 1.5 N/cm, preferably more than 2.5 N/cm, and in a dynamic shear strength for the crosslinked system on glass of more than 25 N/cm², preferably greater than 50 N/cm², very preferably greater than 100 N/cm²

Further details, objectives, features and advantages of the present invention are elucidated in more detail below with reference to a number of figures which show preferred exemplary embodiments:

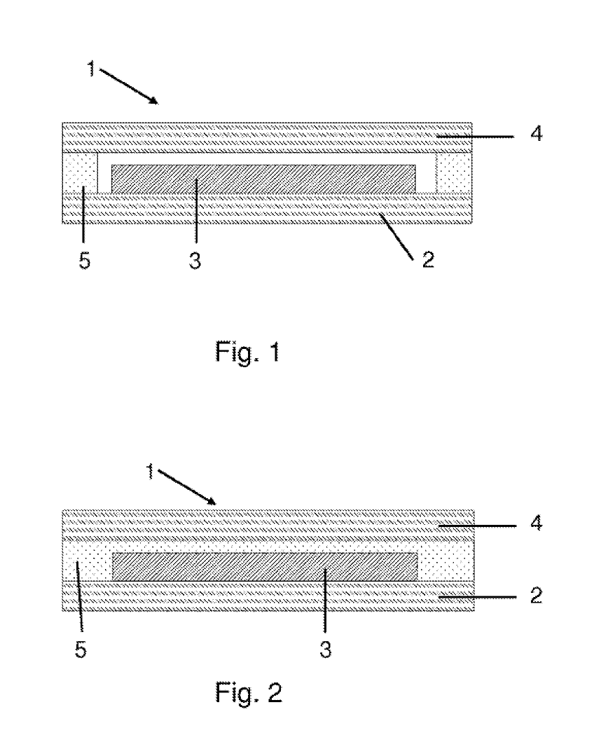

FIG. 1 shows a first (opto)electronic arrangement in a diagrammatic representation,

FIG. 2 shows a second (opto)electronic arrangement in a diagrammatic representation,

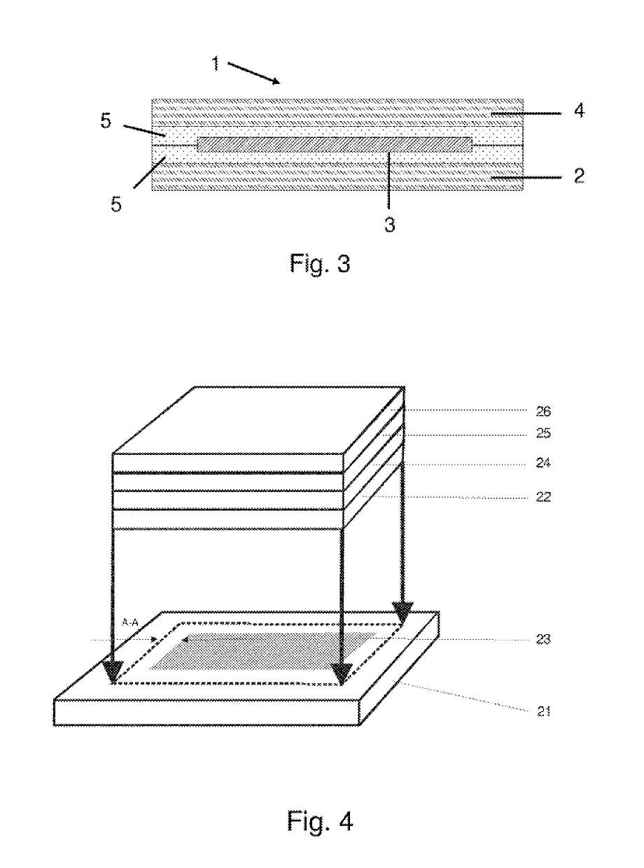

FIG. 3 shows a third (opto)electronic arrangement in a diagrammatic representation.

FIG. 1 shows a first embodiment of an (opto)electronic arrangement 1. This arrangement 1 has a substrate 2 on which an electronic structure 3 is disposed. Substrate 2 itself is designed as a barrier for permeants and thus forms part of the encapsulation of the electronic structure 3. Disposed above the electronic structure 3, in the present case also at a distance from it, is a further cover 4 designed as a barrier.

In order to encapsulate the electronic structure 3 to the side as well and at the same time to join the cover 4 to the electronic arrangement 1 in its remaining part, a pressure-sensitive adhesive (PSA) 5 runs round adjacent to the electronic structure 3 on the substrate 2. In other embodiments the encapsulation is accomplished not with a pure PSA 5, but instead with an adhesive tape 5 which comprises at least one PSA of the invention. The PSA 5 joins the cover 4 to the substrate 2. By means of an appropriately thick embodiment, moreover, the PSA 5 allows the cover 4 to be distanced from the electronic structure 3.

The PSA 5 is of a kind based on the PSA of the invention as described above in general form and set out in more detail below in exemplary embodiments. In the present case, the PSA 5 not only takes on the function of joining the substrate 2 to the cover 4 but also, furthermore, provides a barrier layer for permeants, in order thus to encapsulate the electronic structure 3 from the side as well with respect to permeants such as water vapour and oxygen.

In the present case, furthermore, the PSA 5 is provided in the form of a diecut comprising a double-sided adhesive tape. A diecut of this kind permits particularly simple application.

FIG. 2 shows an alternative embodiment of an (opto)electronic arrangement 1. Shown, again, is an electronic structure 3 which is disposed on a substrate 2 and is encapsulated by the substrate 2 from below. Above and to the side of the electronic structure, the PSA 5 is now in a full-area disposition. The electronic structure 3 is therefore encapsulated fully from above by the PSA 5. A cover 4 is then applied to the PSA 5. This cover 4, in contrast to the previous embodiment, need not necessarily fulfil the high barrier requirements, since the barrier is provided by the PSA itself. The cover 4 may merely, for example, take on a mechanical protection function, or else may also be provided as a permeation barrier.

FIG. 3 shows a further alternative embodiment of an (opto)electronic arrangement 1. In contrast to the previous embodiments, there are now two PSAs 5a, 5b, which in the present case are identical in configuration. The first PSA 5a is disposed over the full area of the substrate 2. The electronic structure 3 is provided on the PSA 5a, and is fixed by the PSA 5a. The assembly comprising PSA 5a and electronic structure 3 is then covered over its full area with the other PSA, 5b, with the result that the electronic structure 3 is encapsulated on all sides by the PSAs 5a, b. Provided above the PSA 5b, in turn, is the cover 4.

In this embodiment, therefore, neither the substrate 2 nor the cover 4 need necessarily have barrier properties. Nevertheless, they may also be provided, in order to restrict further the permeation of permeants to the electronic structure 3.

In relation to FIG. 2, 3 in particular it is noted that in the present case these are diagrammatic representations. From the representations it is not apparent in particular that the PSA 5, here and preferably in each case, is applied with a homogeneous layer thickness. At the transition to the electronic structure, therefore, there is not a sharp edge, as it appears in the representation, but instead the transition is fluid and it is possible instead for small unfilled or gas-filled regions to remain. If desired, however, there may also be conformation to the substrate, particularly when application is carried out under vacuum or under increased pressure. Moreover, the PSA is compressed to different extents locally, and so, as a result of flow processes, there may be a certain compensation of the difference in height of the edge structures. The dimensions shown are also not to scale, but instead serve rather only for more effective representation. In particular, the electronic structure itself is usually of relatively flat design (often less than 1 μm thick).

In all of the exemplary embodiments shown, the PSA 5 is applied in the form of a pressure-sensitive adhesive tape. This may in principle be a double-sided pressure-sensitive adhesive tape with a carrier, or may be an adhesive transfer tape. In the present case, an adhesive transfer tape embodiment is selected.

The thickness of the PSA, present either as an adhesive transfer tape or as a coating on a sheetlike structure, is preferably between about 1 μm and about 150 μm, more preferably between about 5 μm and about 75 μm, and very preferably between about 12 μm and 50 μm. High layer thicknesses between 50 μm and 150 μm are employed when the aim is to achieve improved adhesion to the substrate and/or a damping effect within the (opto)electronic construction. A disadvantage here, however, is the increased permeation cross section. Low layer thicknesses between 1 μm and 12 μm reduce the permeation cross section, and hence the lateral permeation and the overall thickness of the (opto)electronic construction. However, there is a reduction in the adhesion on the substrate. In the particularly preferred thickness ranges, there is a good compromise between a low thickness of composition and the consequent low permeation cross section, which reduces the lateral permeation, and a sufficiently thick film of composition to produce a sufficiently adhering bond. The optimum thickness is dependent on the (opto)electronic construction, on the end application, on the nature of the embodiment of the PSA, and, possibly, on the sheetlike substrate.

For double-sided adhesive tapes it is likewise the case, for the barrier adhesive or adhesives, that the thickness of the individual layer or layers of PSA is preferably between about 1 μm and about 150 μm, more preferably between about 5 μm and about 75 μm, and very preferably between about 12 μm and 50 μm. If a further barrier adhesive is used in double-sided adhesive tapes as well as an inventive barrier adhesive, then it may also be advantageous for the thickness of said further barrier adhesive to be more than 150 μm.

The invention is elucidated in more detail below by means of a number of examples, without thereby wishing to restrict the invention.

### TEST METHODS

### Bond Strength

The bond strength was determined as follows: The defined substrates used were glass plates (float glass). A 36 μm PET film was laminated onto the bondable sheetlike element on the side of the less strongly releasing liner. The bondable sheetlike element under investigation was cut to a width of 20 mm and a length of about 25 cm, provided with a handling section, and immediately thereafter pressed onto the selected substrate five times, using a 4 kg steel roller with a rate of advance of 10 m/min in each case. Immediately thereafter the above-bonded sheetlike element was peeled from the substrate at an angle of 180° at room temperature and at 300 mm/min, using a tensile testing instrument (from Zwick), and the force required to achieve this was recorded. The measurement (in N/cm) was obtained as the average from three individual measurements. The testing was performed on non-crosslinked specimens.

### Permeability for Oxygen (OTR) and Water Vapour (WVTR)

The permeability for oxygen (OTR) and water vapour (WVTR) was determined in accordance with DIN 53380 Part 3 and ASTM F-1249, respectively. For this purpose the PSA is applied with a layer thickness of 50 μm to a permeable membrane. The oxygen permeability is measured at 23° C. and a relative humidity of 50% using a Mocon OX-Tran 2/21 instrument. The water vapour permeability is determined at 37.5° C. and a relative humidity of 90%.

### Lifetime Test

As a measure for determining the lifetime of an electronic construction, a calcium test was employed. This is shown in FIG. 4. For this purpose, in vacuo, a thin layer 23 of calcium, measuring 20×20 mm², was deposited onto a glass plate 21 and subsequently stored under a nitrogen atmosphere. The thickness of the calcium layer 23 is approximately 100 nm. The calcium layer 23 is encapsulated using an adhesive tape (26×26 mm²) with the adhesive 22 to be tested and a flexible thin glass plate 24 (35 μm, Schott) as support material. For the purpose of stabilization, the thin glass sheet was laminated to a PET film 26 that had a thickness of 100 μm, using an adhesive transfer tape 25 that was 50 μm thick and comprised an acrylate PSA of high optical transparency. The adhesive 22 is applied to the glass plate 21 in such a way that the adhesive 22 covers the calcium mirror 23 with an all-round margin of 3 mm (A-A). Owing to the opaque glass carrier 24 the permeation is determined only through the PSA or along the interfaces.

The test is based on the reaction of calcium with water vapour and oxygen, as described, for example, by A. G. Erlat et. al. in “47th Annual Technical Conference Proceedings—Society of Vacuum Coaters”, 2004, pages 654 to 659, and by M. E. Gross et al. in “46th Annual Technical Conference Proceedings—Society of Vacuum Coaters”, 2003, pages 89 to 92. The light transmittance of the calcium layer is monitored, and increases as a result of the conversion into calcium hydroxide and calcium oxide. With the test set-up described, this takes place from the margin, and so there is a reduction in the visible area of the calcium mirror. The time taken for the light absorption of the calcium mirror to be halved is termed the lifetime. The method detects not only the reduction in the area of the calcium mirror from the margin and as a result of local reduction in the area, but also the homogeneous decrease in the layer thickness of the calcium mirror as a result of full-area reduction.

The measurement conditions selected were 60° C. and 90% relative humidity. The specimens were bonded in full-area form, without bubbles, with a PSA layer thickness of 25 μm. The measurement (in h) was obtained as the average value from three individual measurements.

From the time for complete reduction in the calcium mirror, moreover, a water vapour permeation rate (Ca-WVTR) is calculated. For this calculation, the mass of calcium applied by vapour deposition is multiplied by a factor of 0.9 (mass ratio H₂O/Ca for the conversion reaction of metallic calcium to transparent calcium hydroxide) in order to determine the mass of water vapour which has permeated in. This mass is based on the permeation cross section (peripheral length of the test set-up×thickness of adhesive) and also on the time for complete reduction in the calcium mirror. The measurement value calculated is further divided by the width of the all-round margin (in mm) and hence standardized to a permeation distance of 1 mm. The Ca-WVTR is reported in g/m^{2*}d.

### Tackifier Resin Softening Temperature

The tackifier resin softening temperature is conducted according to the relevant methodology, which is known as ring and ball and is standardized according to ASTM E28.

The tackifier resin softening temperature of the resins is determined using an automatic ring & ball tester HRB 754 from Herzog. Resin specimens are first finely mortared. The resulting powder is introduced into a brass cylinder with a base aperture (internal diameter at the top part of the cylinder 20 mm, diameter of the base aperture in the cylinder 16 mm, height of the cylinder 6 mm) and melted on a hotplate. The amount introduced is selected such that the resin after melting fully fills the cylinder without protruding.

The resulting sample body, complete with cylinder, is inserted into the sample mount of the HRB 754. Glycerin is used to fill the heating bath where the tackifier resin softening temperature lies between 50° C. and 150° C. For lower tackifier resin softening temperatures, it is also possible to operate with a waterbath. The test balls have a diameter of 9.5 mm and weigh 3.5 g. In line with the HRB 754 procedure, the ball is arranged above the sample body in the heating bath and is placed down on the sample body. 25 mm beneath the base of the cylinder is a collecting plate, with a light barrier 2 mm above it. During the measuring procedure, the temperature is raised at 5° C/min. Within the temperature range of the tackifier resin softening temperature, the ball begins to move through the base aperture in the cylinder, until finally coming to rest on the collecting plate. In this position, it is detected by the light barrier, and at this point in time the temperature of the heating bath is recorded. A duplicate determination is conducted. The tackifier resin softening temperature is the average value from the two individual measurements.

### Softening Temperature

The softening temperature of copolymers, hard blocks and soft blocks and uncured reactive resins is determined calorimetrically by means of differential scanning calorimetry (DSC) in accordance with DIN 53765:1994-03. Heating curves run with a heating rate of 10 K/min. The specimens are measured in Al crucibles with a perforated lid under a nitrogen atmosphere. The heating curve evaluated is the second curve. In the case of amorphous substances, there are glass transition temperatures; in the case of (semi-)crystalline substances, there are melting temperatures. A glass transition can be seen as a step in the thermogram. The glass transition temperature is evaluated as the middle point of this step. A melting temperature can be recognized as a peak in the thermogram. The melting temperature recorded is the temperature at which maximum heat change occurs.

### Transmittance

The transmittance of the adhesive was determined via the VIS spectrum. The VIS spectrum was recorded on a Kontron UVIKON 923. The wavelength range of the spectrum measured encompasses all wavelengths between 800 nm and 400 nm, with a resolution of 1 nm. A blank channel measurement was carried out over the entire wavelength range, as a reference. For the reporting of the result, the transmittance measurements within the stated range were averaged. There is no correction for interfacial reflection losses.

### HAZE Measurement

The HAZE value describes the fraction of transmitted light which is scattered forward at large angles by the irradiated sample. The HAZE value hence quantifies material defects in the surface or the structure that disrupt clear transmission.

The method for measuring the Haze value is described in the ASTM D 1003 standard. This standard requires the recording of four transmittance measurements. For each transmittance measurement, the degree of transmittance is calculated. The four transmittances are used to calculate the percentage haze value. The HAZE value is measured using a Haze-gard Dual from Byk-Gardner GmbH.

### Molecular Weight

The average molecular weight M_{W} (weight average)—also referred to as molar mass - is determined by means of gel permeation chromatography (GPC). The eluent used is THF with 0.1% by volume trifluoroacetic acid. Measurement takes place at 25° C. The preliminary column used is PSS-SDV, 5 μm, 10³ Å, ID 8.0 mm×50 mm. Separation was carried out using the columns PSS-SDV, 5 μm, 10³ Å, 10⁵ Å and 10⁶ Å, each with an ID of 8.0 mm×300 mm. The sample concentration is 4 g/l, the flow rate 1.0 ml per minute. Measurement takes place against PS standards.

### Dynamic Shear Test

An adhesive transfer tape is bonded between two glass plates (float glass) and cured using UV light. After storage for 24 hours, the assembly is parted in the tensile testing machine at 50 mm/min, at 23° C. and 50% relative humidity, by the two glass plates being pulled apart at an angle of 180°, the maximum force in N/cm² being recorded. In this case the test specimen investigated is a square specimen having an edge length of 25 mm.

Unless otherwise indicated, all quantities in the examples which follow are weight percentages or parts by weight, based on the overall composition.

### Example 1

The copolymer selected was a polystyrene-block-polyisobutylene block copolymer from Kaneka. The fraction of styrene in the overall polymer is 20 wt %. Sibstar 62M (300 g) was used. The molar mass is 60 000 g/mol. The glass transition temperature of the polystyrene blocks was 100° C. and that of the polyisobutylene blocks −60° C. The tackifier resin employed was Escorez 5300 (Ring & Ball 105° C., DACP=71, MMAP=72) from Exxon, a fully hydrogenated hydrocarbon resin (200 g). The reactive resin selected was Uvacure 1500 from Dow, a cycloaliphatic diepoxide (500 g). The glass transition temperature of Uvacure 1500 was −53° C. These raw materials were dissolved in a mixture of toluene (300 g), acetone (150 g) and special-boiling-point spirit 60/95 (550 g), to give a 50% by weight solution.

A photoinitiator was then added to the solution. For this purpose, 10 g of triarylsulphonium hexafluoroantimonate (acquired from Sigma Aldrich) were weighed off. The photoinitiator was in the form of a 50% by weight solution in propylene carbonate. The photoinitiator has an absorption maximum in the 320 nm to 360 nm range.

Using a knifecoating procedure, the formulation was coated from solution onto a siliconized PET liner and then dried at 120° C. for 15 minutes. The coatweight was 50 g/m². The specimen was lined with a further ply of a siliconized but less strongly releasing PET liner.

These specimens were used to produce samples for bond strength measurements. The bond strength on glass (float glass) was 4.2 N/cm. In addition, specimens were produced for dynamic shear tests (curing took place with an undoped mercury lamp, using a dose of 80 mJ/cm²). The test for dynamic shear strength gave a result of 150 N/cm².

The specimens were inserted into a glove box. Some of the specimens were subjected to the lifetime test. In this case, curing took place through the cover glass by means of UV light (dose: 80 mJ/cm²; lamp type: undoped mercury emitter). This specimen was used for the lifetime test. Further specimens were cured by UV, without prior lamination, under the same conditions as indicated above, through the PET liner. These specimens were used for WVTR and OTR measurements (Mocon) and for the testing of optical properties.

The result from the WVTR measurement (Mocon) was 9 g/m^{2*}d, and from the OTR measurement (Mocon) 800 cm³/m²*d*bar. The lifetime test, determined from the alteration of a Ca dot over time (Ca-WVTR), gave a result of 0.8 g/m²*d.

Investigation of the optical properties of the cured specimens following removal of both PET liners produced a transmittance of 91% and a haze of 1.5%.

### Example 2

The copolymer selected was a polystyrene-block-polyisobutylene block copolymer from Kaneka. The fraction of styrene in the polymer as a whole is 30 wt %. Sibstar 103T was used (300 g). The molar mass is 100 000 g/mol. The glass transition temperature of the polystyrene blocks was 100° C., and that of the polyisobutylene blocks −60° C. As a tackifier resin, use was made of Regalite R1100 (ring and ball 100° C., DACP=45, MMAP=82) from Eastman, a fully hydrogenated hydrocarbon resin (200 g). The reactive resin selected was Bakelite EPR 166 from Momentive, a bisphenol A diepoxide (500 g). The glass transition temperature of EPR 166 was −19° C. These raw materials were dissolved in a mixture of toluene (300 g), acetone (150 g) and special-boiling-point spirit 60/95 (550 g), to give a 50 wt % solution.

Subsequently, a photoinitiator is added to the solution. For this purpose, 10 g of triarylsulphonium hexafluorophosphate (acquired from Sigma Aldrich) were weighed out. The photoinitiator was in the form of a 50% by weight solution in propylene carbonate. The photoinitiator has an absorption maximum in the 320 nm to 360 nm range.

Using a knifecoating procedure, the formulation was applied from solution to a siliconized PET liner and the coating was dried at 120° C. for 15 minutes. The coatweight was 50 g/m². The specimen was lined with a further ply of a siliconized but less strongly releasing PET liner.

These specimens were used to produce samples for bond strength measurements. The bond strength on glass (float glass) was 3.5 N/cm. In addition, specimens were produced for dynamic shear tests. The test for dynamic shear strength gave a result of 200 N/cm².

The specimens were inserted into a glove box. Some of the specimens were subjected to the lifetime test. In this case, curing was carried out through the cover glass, using UV light (dose: 80 mJ/cm²; lamp type: undoped mercury lamp). This specimen was used for the lifetime test. Further specimens were cured by UV, without prior lamination, under the same conditions as indicated above, through the PET liner. These specimens were used for WVTR and OTR measurements (Mocon) and for the testing of optical properties.

The result from the WVTR measurement (Mocon) was 9 g/m²*d, and from the OTR measurement (Mocon) 860 cm³/m²*d*bar. The lifetime test, determined from the alteration of a Ca dot over time (Ca-WVTR), gave a result of 0.9 g/m²*d.

Investigation of the optical properties of the cured specimens following removal of both PET liners produced a transmittance of 75% and a haze of 5%.

### Example 3

The copolymer selected was a polystyrene-block-polyisobutylene block copolymer from Kaneka. The fraction of styrene in the polymer as a whole is 30 wt %. Sibstar 73 T was used at 300 g. The molar mass is 70 000 g/mol. The glass transition temperature of the polystyrene blocks is 100° C., and that of the polyisobutylene blocks −60° C. As a tackifier resin, use was made of Regalite R1100 (ring and ball 100° C., DACP=45, MMAP=82) from Eastman, a fully hydrogenated hydrocarbon resin, at 200 g. The reactive resin selected was Uvacure 1500 from Cytec, at 500 g. The glass transition temperature of Uvacure 1500 is −53° C. These raw materials were dissolved in a mixture of toluene (300 g), acetone (150 g) and special-boiling-point spirit 60/95 (550 g), to give a 50 wt % solution.

Subsequently, a photoinitiator was added to the solution. For this purpose, 10 g of [4-(1-methylethyl)phenyl](4-methylphenyl)iodonium tetrakis(pentafluorophenyl)borate, Silicolease UV Cata 211 (Bluestar Silicones) were weighed out. The photoinitiator was in the form of a 20% by weight solution in isopropanol.

Using a knifecoating procedure, the formulation was applied from solution to a siliconized PET liner and the coating was dried at 120° C. for 15 min. The coatweight was 50 g/m². The specimen was lined with a further ply of a siliconized but less strongly releasing PET liner.

These specimens were used to produce samples for bond strength measurements.

The bond strength on glass (float glass) was 3.2 N/cm. In addition, specimens were produced for dynamic shear tests. The test for dynamic shear strength gave a result of 180 N/cm².

The specimens were inserted into a glove box. Some of the specimens were subjected to the lifetime test. In this case, curing took place through the cover glass by means of UV light (dose: 80 mJ/cm²; lamp type: undoped mercury emitter). The specimen was used for the lifetime test. Further specimens were cured by UV, without prior lamination, under the same conditions as indicated above, through the PET liner. The specimens were used for WVTR and OTR measurements (Mocon) and for the testing of optical properties.

The result from the WVTR measurement (Mocon) was 6 g/m²*d, and from the OTR measurement (Mocon) 412 cm³/m²*d*bar. The lifetime test, determined from the alteration of a Ca dot over time (Ca-WVTR), gave a result of 0.3 g/m²*d.

Investigation of the optical properties of the cured specimens following removal of both PET liners produced a transmittance of 90% and a haze of 1.9%.

### Example 4

The copolymer selected was a polystyrene-block-polyisobutylene block copolymer from Kaneka. The fraction of styrene in the polymer as a whole is 20 wt %. Sibstar 62M was used at 425 g. The molar mass is 60 000 g/mol. The glass transition temperature of the polystyrene blocks is 100° C., and that of the polyisobutylene blocks −60° C. As a tackifier resin, use was made of Escorez 5300 (ring and ball 105° C., DACP=71, MMAP=72) from Exxon, a fully hydrogenated hydrocarbon resin, at 425 g. The reactive resin selected was Uvacure 1500 from Dow, a cycloaliphatic diepoxide, at 150 g. The glass transition temperature of Uvacure 1500 is −53° C. These raw materials were dissolved in a mixture of toluene (300 g), acetone (150 g) and special-boiling-point spirit 60/95 (550 g), to give a 50 wt % solution.

Subsequently, a photoinitiator was added to the solution. For this purpose, 3 g of triarylsulphonium hexafluoroantimonate (acquired from Sigma Aldrich) were weighed out.

The photoinitiator was in the form of a 50% by weight solution in propylene carbonate. The photoinitiator has an absorption maximum in the 320 nm to 360 nm range.

Using a knifecoating procedure, the formulation was applied from solution to a siliconized PET liner and the coating was dried at 120° C. for 15 min. The coatweight was 50 g/m². The specimen was lined with a further ply of a siliconized but less strongly releasing PET liner.

These specimens were used to produce samples for bond strength measurements. The bond strength on glass (float glass) was 7.1 N/cm. In addition, specimens were produced for dynamic shear tests (the curing was effected with an undoped mercury lamp with a dose of 80 mJ/cm²). The test for dynamic shear strength gave a result of 100 N/cm².

The specimens were inserted into a glove box. Some of the specimens were subjected to the lifetime test. In this case, curing took place through the cover glass by means of UV light (dose: 80 mJ/cm²; lamp type: undoped mercury emitter). The specimen was used for the lifetime test. Further specimens were cured by UV, without prior lamination, under the same conditions as indicated above, through the PET liner. The specimens were used for WVTR and OTR measurements (Mocon) and for the testing of optical properties.

The result from the WVTR measurement (Mocon) was 9 g/m²*d, and from the OTR measurement (Mocon) 900 cm³/m²*d*bar. The lifetime test, determined from the alteration of a Ca dot over time (Ca-WVTR), gave a result of 0.4 g/m²*d.

Investigation of the optical properties of the cured specimens following removal of both PET liners produced a transmittance of 93% and a haze of 1.4%.

### Example 5

The copolymer selected was a polystyrene-block-polyisobutylene block copolymer from Kaneka. The fraction of styrene in the polymer as a whole is 20 wt %. Sibstar 62M was used at 400 g. The molar mass is 60 000 g/mol. The glass transition temperature of the polystyrene blocks is 100° C., and that of the polyisobutylene blocks −60° C. As a tackifier resin, use was made of Escorez 5300 (ring and ball 105° C., DACP=71, MMAP=72) from Exxon, a fully hydrogenated hydrocarbon resin, at 400 g. The reactive resin selected was Uvacure 1500 from Dow, a cycloaliphatic diepoxide, at 200 g. The glass transition temperature of Uvacure 1500 is −53° C. These raw materials were dissolved in a mixture of toluene (300 g), acetone (150 g) and special-boiling-point spirit 60/95 (550 g), to give a 50 wt % solution.

Subsequently, a photoinitiator was added to the solution. For this purpose, 4 g of triarylsulphonium hexafluoroantimonate (acquired from Sigma Aldrich) were weighed out. The photoinitiator was in the form of a 50% by weight solution in propylene carbonate. The photoinitiator has an absorption maximum in the 320 nm to 360 nm range.

Using a knifecoating procedure, the formulation was applied from solution to a siliconized PET liner and the coating was dried at 120° C. for 15 min. The coatweight was 50 g/m². The specimen was lined with a further ply of a siliconized but less strongly releasing PET liner.

These specimens were used to produce samples for bond strength measurements. The bond strength on glass (float glass) was 6.2 N/cm. In addition, specimens were produced for dynamic shear tests (the curing was effected with an undoped mercury lamp with a dose of 80 mJ/cm²). The test for dynamic shear strength gave a result of 150 N/cm².

The specimens were inserted into a glove box. Some of the specimens were subjected to the lifetime test. In this case, curing took place through the cover glass by means of UV light (dose: 80 mJ/cm²; lamp type: undoped mercury emitter). The specimen was used for the lifetime test. Further specimens were cured by UV, without prior lamination, under the same conditions as indicated above, through the PET liner. The specimens were used for WVTR and OTR measurements (Mocon) and for the testing of optical properties.

The result from the WVTR measurement (Mocon) was 9 g/m²*d, and from the OTR measurement (Mocon) 900 cm³/m²*d*bar. The lifetime test, determined from the alteration of a Ca dot over time (Ca-WVTR), gave a result of 0.3 g/m²*d.

Investigation of the optical properties of the cured specimens following removal of both PET liners produced a transmittance of 93% and a haze of 1.4%.

### Example 6

The copolymer selected was a polystyrene-block-polyisobutylene block copolymer from Kaneka. The fraction of styrene in the polymer as a whole is 20 wt %. Sibstar 62H was used at 375 g. The molar mass is 60 000 g/mol. The glass transition temperature of the polystyrene blocks is 100° C., and that of the polyisobutylene blocks −60° C. As a tackifier resin, use was made of Escorez 5300 (ring and ball 105° C., DACP=71, MMAP=72) from Exxon, a fully hydrogenated hydrocarbon resin, at 375 g. The reactive resin selected was Uvacure 1500 from Dow, a cycloaliphatic diepoxide, at 250 g. The glass transition temperature of Uvacure 1500 is −53° C. These raw materials were dissolved in a mixture of toluene (300 g), acetone (150 g) and special-boiling-point spirit 60/95 (550 g), to give a 50 wt % solution.

Subsequently, a photoinitiator was added to the solution. For this purpose, 5 g of triarylsulphonium hexafluoroantimonate (acquired from Sigma Aldrich) were weighed out. The photoinitiator was in the form of a 50% by weight solution in propylene carbonate. The photoinitiator has an absorption maximum in the 320 nm to 360 nm range.

Using a knifecoating procedure, the formulation was applied from solution to a siliconized PET liner and the coating was dried at 120° C. for 15 min. The coatweight was 50 g/m². The specimen was lined with a further ply of a siliconized but less strongly releasing PET liner.

These specimens were used to produce samples for bond strength measurements. The bond strength on glass (float glass) was 6 N/cm. In addition, specimens were produced for dynamic shear tests (the curing was effected with an undoped mercury lamp with a dose of 80 mJ/cm²). The test for dynamic shear strength gave a result of 140 N/cm².

The specimens were inserted into a glove box. Some of the specimens were subjected to the lifetime test. In this case, curing took place through the cover glass by means of UV light (dose: 80 mJ/cm²; lamp type: undoped mercury emitter). The specimen was used for the lifetime test. Further specimens were cured by UV, without prior lamination, under the same conditions as indicated above, through the PET liner. The specimens were used for WVTR and OTR measurements (Mocon) and for the testing of optical properties.

The result from the WVTR measurement (Mocon) was 9 g/m²*d, and from the OTR measurement (Mocon) 798 cm³/m²*d*bar. The lifetime test, determined from the alteration of a Ca dot over time (Ca-WVTR), gave a result of 0.25 g/m²*d.

Investigation of the optical properties of the cured specimens following removal of both PET liners produced a transmittance of 93% and a haze of 1.4%.

### Example 7

The copolymer selected was a polystyrene-block-polyisobutylene block copolymer from Kaneka. The fraction of styrene in the polymer as a whole is 20 wt %. Sibstar 62M was used at 333 g. The molar mass is 60 000 g/mol. The glass transition temperature of the polystyrene blocks is 100° C., and that of the polyisobutylene blocks −60° C. As a tackifier resin, use was made of Escorez 5300 (ring and ball 105° C., DACP=71, MMAP=72) from Exxon, a fully hydrogenated hydrocarbon resin, at 333 g. The reactive resin selected was Uvacure 1500 from Dow, a cycloaliphatic diepoxide, at 333 g. The glass transition temperature of Uvacure 1500 is −53° C. These raw materials were dissolved in a mixture of toluene (300 g), acetone (150 g) and special-boiling-point spirit 60/95 (550 g), to give a 50 wt % solution.

Subsequently, a photoinitiator was added to the solution. For this purpose, 6.6 g of triarylsulphonium hexafluoroantimonate (acquired from Sigma Aldrich) were weighed out. The photoinitiator was in the form of a 50% by weight solution in propylene carbonate. The photoinitiator has an absorption maximum in the 320 nm to 360 nm range.

Using a knifecoating procedure, the formulation was applied from solution to a siliconized PET liner and the coating was dried at 120° C. for 15 min. The coatweight was 50 g/m². The specimen was lined with a further ply of a siliconized but less strongly releasing PET liner.

These specimens were used to produce samples for bond strength measurements.

The bond strength on glass (float glass) was 5.1 N/cm. In addition, specimens were produced for dynamic shear tests (the curing was effected with an undoped mercury lamp with a dose of 80 mJ/cm²). The test for dynamic shear strength gave a result of 270 N/cm².

The specimens were inserted into a glove box. Some of the specimens were subjected to the lifetime test. In this case, curing took place through the cover glass by means of UV light (dose: 80 mJ/cm²; lamp type: undoped mercury emitter). The specimen was used for the lifetime test. Further specimens were cured by UV, without prior lamination, under the same conditions as indicated above, through the PET liner. The specimens were used for WVTR and OTR measurements (Mocon) and for the testing of optical properties.

The result from the WVTR measurement (Mocon) was 9 g/m²*d, and from the OTR measurement (Mocon) 621 cm³/m²*d*bar. The lifetime test, determined from the alteration of a Ca dot over time (Ca-WVTR), gave a result of 0.2 g/m²*d.

Investigation of the optical properties of the cured specimens following removal of both PET liners produced a transmittance of 93% and a haze of 1.4%.

### Example 8

The copolymer selected was a polystyrene-block-polyisobutylene block copolymer from Kaneka. The fraction of styrene in the polymer as a whole is 20 wt %. Sibstar 62M was used at 333 g. The molar mass is 60 000 g/mol. The glass transition temperature of the polystyrene blocks is 100° C., and that of the polyisobutylene blocks −60° C. As a tackifier resin, use was made of Escorez 5300 (ring and ball 105° C., DACP=71, MMAP=72) from Exxon, a fully hydrogenated hydrocarbon resin, at 333 g. The reactive resin selected was Uvacure 1500 from Dow, a cycloaliphatic diepoxide, at 333 g. The glass transition temperature of Uvacure 1500 is −53° C. These raw materials were dissolved in a mixture of toluene (300 g), acetone (150 g) and special-boiling-point spirit 60/95 (550 g), to give a 50 wt % solution.

Subsequently, a photoinitiator was added to the solution. For this purpose, 16.65 g of diaryliodonium tetrakispentafluorophenylborate (acquired from Bluestar Silicon) were weighed out. The photoinitiator was in the form of a 20% by weight solution in propanol. The photoinitiator has an absorption maximum in the 190 nm to 230 nm range and was used in combination with a benzophenone sensitizer (acquired from Sigma Aldrich). For this purpose, 3.33 g were weighed out.

Using a knifecoating procedure, the formulation was applied from solution to a siliconized PET liner and the coating was dried at 120° C. for 15 min. The coatweight was 50 g/m². The specimen was lined with a further ply of a siliconized but less strongly releasing PET liner.

These specimens were used to produce samples for bond strength measurements. The bond strength on glass (float glass) was 5.2 N/cm.

In addition, specimens were produced for dynamic shear tests (the curing was effected with an undoped mercury lamp with a dose of 80 mJ/cm²). The test for dynamic shear strength gave a result of 250 N/cm².

The specimens were inserted into a glove box. Some of the specimens were subjected to the lifetime test. In this case, curing took place through the cover glass by means of UV light (dose: 80 mJ/cm²; lamp type: undoped mercury emitter). The specimen was used for the lifetime test. Further specimens were cured by UV, without prior lamination, under the same conditions as indicated above, through the PET liner. The specimens were used for WVTR and OTR measurements (Mocon) and for the testing of optical properties.

The result from the WVTR measurement (Mocon) was 10 g/m²*d, and from the OTR measurement (Mocon) 730 cm³/m²*d*bar. The lifetime test, determined from the alteration of a Ca dot over time (Ca-WVTR), gave a result of 0.22 g/m²*d.

Investigation of the optical properties of the cured specimens following removal of both PET liners produced a transmittance of 93% and a haze of 1.6%.

### Example 9

A single-sidedly adhesive sheet was produced. For this purpose, as copolymer for the adhesive, a polystyrene-block-polyisobutylene block copolymer from Kaneka was selected. The fraction of styrene in the polymer as a whole is 20 wt %. Sibstar 62H was used at 375 g. The molar mass is 60 000 g/mol. The glass transition temperature of the polystyrene blocks is 100° C., and that of the polyisobutylene blocks −60° C. As a tackifier resin, use was made of Escorez 5300 (ring and ball 105° C., DACP=71, MMAP=72) from Exxon, a fully hydrogenated hydrocarbon resin, at 375 g. As a reactive resin, Uvacure 1500 from Dow was selected, a cycloaliphatic diepoxide, at 250 g. The glass transition temperature of Uvacure 1500 is −53° C. These raw materials were dissolved in a mixture of toluene (300 g), acetone (150 g) and special-boiling-point spirit 60/95 (550 g), to give a 50 wt % solution.

Subsequently, a photoinitiator was added to the solution. For this purpose, 5 g of triarylsulphonium hexafluoroantimonate (acquired from Sigma Aldrich) were weighed out. The photoinitiator was in the form of a 50% by weight solution in propylene carbonate. The photoinitiator has an absorption maximum in the 320 nm to 360 nm range.

Using a knifecoating procedure, the formulation was applied from solution to a siliconized PET liner and the coating was dried at 120° C. for 15 minutes. The coatweight was 50 g/m². The specimen was lined with a ply of a flexible thin glass (D 263 T from Schott in 30 μm thickness).

The specimens were inserted into a glove box. Some of the specimens were subjected to the lifetime test. In this case, curing was carried out through the thin glass carriers, using UV light (dose: 80 mJ/cm²; lamp type: undoped mercury emitter). This specimen was used for the lifetime test (Ca test), which gave a Ca-WVTR of 0.26 g/m²d.

### Example 10

A single-sidedly adhesive sheet was produced. For this purpose, as copolymer for the adhesive, a polystyrene-block-polyisobutylene block copolymer from Kaneka was selected. The fraction of styrene in the polymer as a whole is 20 wt %. Sibstar 62H was used at 375 g. The molar mass is 60 000 g/mol. The glass transition temperature of the polystyrene blocks is 100° C., and that of the polyisobutylene blocks −60° C. As a tackifier resin, use was made of Escorez 5300 (ring and ball 105° C., DACP=71, MMAP=72) from Exxon, a fully hydrogenated hydrocarbon resin, at 375 g. As a reactive resin, Uvacure 1500 from Dow was selected, a cycloaliphatic diepoxide, at 250 g. The glass transition temperature of Uvacure 1500 is −53° C. These raw materials were dissolved in a mixture of toluene (300 g), acetone (150 g) and special-boiling-point spirit 60/95 (550 g), to give a 50 wt % solution.

Subsequently, a photoinitiator was added to the solution. For this purpose, 5 g of triarylsulphonium hexafluoroantimonate (acquired from Sigma Aldrich) were weighed out. The photoinitiator was in the form of a 50% by weight solution in propylene carbonate. The photoinitiator has an absorption maximum in the 320 nm to 360 nm range.

Using a knifecoating procedure, the formulation was applied from solution to a siliconized PET liner and the coating was dried at 120° C. for 15 minutes. The coatweight was 50 g/m². The specimen was lined with a further ply of a siliconized but less strongly releasing PET liner.

These specimens were used to produce samples for bond strength measurements. The bond strength on glass (float glass) was 6 N/cm. In addition, specimens were produced for dynamic shear tests (the curing was effected with an undoped mercury lamp with a dose of 80 mJ/cm²). The test for dynamic shear strength gave a result of 140 N/cm².

A 25 μm-thick optically clear adhesive transfer tape (tesa 69101) was laminated onto a 50 μm-thick optically clear polyester film (Melinex 723). The second liner of the adhesive transfer tape was peeled off and the specimen was lined with a ply of a flexible thin glass (D 263 T from Schott in 30 μm thickness). The free side of the 50 g/m² polystyrene-block-polyisobutylene block copolymer-based adhesive sheet was laminated onto this assembly, on the free side of the thin glass.

The specimens were inserted into a glove box. Some of the specimens were subjected to the lifetime test. In this case, curing was carried out through the thin glass assembly carriers, using UV light (dose: 80 mJ/cm²; lamp type: undoped mercury emitter). This specimen was used for the lifetime test (Ca test), which gave a Ca-WVTR of 0.26 g/m²d.

The examples demonstrate not only the particular suitability of the adhesive of the invention but also the successful use of an adhesive tape having a thin glass or thin-glass laminate as carrier material for an adhesive tape for encapsulation to counter permeants.

1. An adhesive for encapsulating an electronic arrangement, the adhesive comprising
(a) at least one copolymer comprising at least isobutylene or butylene as comonomer kind and at least one comonomer kind which has a softening temperature of greater than 40° C.,
(b) at least one kind of an at least partly hydrogenated tackifier resin,
(c) at least one kind of a reactive resin based on cyclic ethers having a softening temperature of less than 40° C., and
(d) at least one kind of a photoinitiator for initiating cationic curing.

2. The adhesive according to claim 1, wherein the copolymer or copolymers is or are random, alternating, block, star and/or graft copolymers having a molar mass M_{W}, of 300 000 g/mol or less.

3. The adhesive according to claim 1, wherein the copolymer or copolymers is or are block, star and/or graft copolymers which contain at least one kind of a first soft polymer block having a softening temperature of less than −20° C. and at least one kind of a second hard polymer block having a softening temperature of greater than +40° C.

4. The adhesive according to claim 3, wherein the first soft polymer block is of apolar construction and comprises butylene or isobutylene as homopolymer block or copolymer block, wherein, when the first soft polymer block is copolymer block, the first soft polymer block is copolymerized with itself or with one another or with further comonomers.

5. The adhesive according to claim 3, wherein the second hard polymer block is constructed from styrene, styrene derivatives and/or from other aromatic or (cyclo)aliphatic hydrocarbon monomers or from methacrylates or from acrylates.

6. The adhesive according to claim 3 wherein
at least one block copolymer is a triblock copolymer constructed from two terminal hard blocks and one middle soft block.

7. The adhesive according to claim 1 wherein
the tackifier resin or resins has or have a degree of hydrogenation of at least 70%.

8. The adhesive according to claim 1 wherein
the adhesive comprises at least one resin which has a DACP of more than 30° C. and a MMAP of more than 50° C.

9. The adhesive according to claim 1 wherein
the adhesive comprises at least one reactive resin that carries at least one epoxy group or at least one oxetane group.

10. The adhesive according to claim 1 wherein
the adhesive comprises at least one reactive resin which is aliphatic or cycloaliphatic in nature.

11. The adhesive according to claim 1 wherein
the adhesive comprises photoinitiators that absorb UV light below 350 nm, that permit cationic curing, and that include sulphonium, iodonium and metallocene-based systems.

12. The adhesive according to claim 11 wherein the
photoinitiators absorb UV light above 250 nm and below 350 nm.

13. The adhesive according to claim 1 wherein the adhesive is a
pressure-sensitive adhesive that comprises one or more additives selected from the group consisting of plasticizers, primary antioxidants, secondary antioxidants, process stabilizers, light stabilizers, processing assistants, endblock reinforcer resins, and polymers.

14. The adhesive according to claim 13 wherein
the pressure-sensitive adhesive comprises one or more nanoscale fillers, transparent fillers and/or getter and/or scavenger fillers.

15. The adhesive according to claim 1 wherein
the adhesive is transparent in the visible light of the spectrum having a wavelength range from about 400 nm to 800 nm.

16. The adhesive according to claim 1 wherein
the adhesive exhibits a haze of less than 5.0%.

17. An adhesive tape comprising at least one layer of the adhesive according to claim 1 and a carrier, wherein the carrier has a permeation barrier of WVTR<0.1 g/(m² d) and OTR<0.1 cm³/(m² d bar).

18. The adhesive tape according to claim 17, wherein the carrier is a coated polymeric film.

19. The adhesive tape according to claim 17, wherein the carrier has a layer of a flexible thin glass with a layer thickness of not more 100 μm, wherein the thin glass is a borosilicate glass or an alkali-free aluminoborosilicate glass.

20. The adhesive according to claim 19, wherein the thin glass is present in a tape-like geometry.

21. A method for encapsulating an electronic arrangement, the method comprising:
encapsulating an (opto) electronic arrangement with the adhesive according to claim 1.

22. The method according to claim 21, wherein the adhesive or regions of the (opto)electronic arrangement that are to be encapsulated with the adhesive are heated before, during or after application of the adhesive.

23. The method according to claim 21, wherein the adhesive is cured partly or to completion on the electronic arrangement after application.

24. An electronic arrangement having an organic electronic structure, and a pressure-sensitive adhesive, the electronic structure being at least partly encapsulated by the pressure-sensitive adhesive, wherein
the pressure-sensitive adhesive comprises the adhesive according to claim 1.
